(19) United States
(12) Patent Application Publication
(10) Pub. No.: US 2026/0056237 A1
(43) Pub. Date: Feb. 26, 2026

(54) System and Methods for the Detection and Mitigation of Cavitation in Rotating Equipment

(71) Applicant: AB Cognitive Systems Inc., Calgary (CA)

(72) Inventor: Amir BADKOUBEH, Calgary (CA)

(73) Assignee: AB Cognitive Systems Inc., Calgary (CA)

(21) Appl. No.: 19/070,653

(22) Filed: Mar. 5, 2025

Related U.S. Application Data
(60) Provisional application No. 63/685,364, filed on Aug. 21, 2024.

(51) Int. Cl. G01R 21/06

(52) U.S. Cl. CPC G01R 21/06

(57) ABSTRACT

A system for monitoring operation of electrical rotating liquid-moving machinery. The system comprises sensors configured to measure electrical signals including the current of the electrical rotating liquid-moving machinery. A remote processor identifies the frequency components of the measured electrical signals. Based on the noise in the frequency components within a frequency band, cavitation within the liquid can be identified. This may help allow the system to be controlled to mitigate the effects of such cavitation.

### RELATED APPLICATIONS

This application claims priority from U.S. Provisional Application No. 63/685,364 filed on Aug. 21, 2024, and entitled “System and Methods for the Detection and Mitigation of Cavitation in Rotating Equipment” and hereby incorporated by reference in its entirety.

### FIELD OF THE INVENTION

The present disclosure is directed to systems and methods for detection, quantification and mitigation of cavitation in a pump or other electrical rotating liquid-moving machinery.

### BACKGROUND

Electric rotating machinery includes electric motors; electrical generators; motor-generators; and rotary transformers.

An electric motor is an electrical machine that converts electrical energy into mechanical energy. Most electric motors operate through the interaction between the motor's magnetic field and electric current in a wire winding to generate force in the form of torque applied on the motor's shaft. Electric motors can be powered by direct current (DC) sources, such as from batteries, motor vehicles or rectifiers, or by alternating current (AC) sources, such as a power grid, inverters or electrical generators. A variable speed drive (VSD) or variable frequency drive (VFD) is commonly used to control and regulate the speed of electric motors.

Electrical rotating liquid-moving machinery is designed to interact with a liquid, and may include pumps, agitators, impellers and propellers. Cavitation can occur when gas is present within the liquid interacting with the electrical rotating liquid-moving machinery. For example, when a pump or propeller is driven above a certain speed within a liquid, cavitation can occur, although the precise conditions which give rise to cavitation can be unpredictable. Cavitation may also occur when there is gas present in the fluid interacting with the Electrical rotating liquid-moving machinery. Cavitation may adversely affect the performance of the machinery. For example, in the context of a pump, cavitation may prevent liquid passing through the pump.

### SUMMARY

In accordance with the present disclosure, there is provided a system for monitoring operation of electrical rotating liquid-moving machinery, the system comprising:
sensors configured to measure electrical signals of the electrical rotating liquid-moving machinery, the measured electrical signals comprising at least one current; and
a processor configured to:
   receive the measured electrical signals and to generate a frequency spectrum based on the measured electrical signals;
   determine a flow noise index corresponding to the noise present within a frequency band within the generated frequency spectrum; and
   determine when cavitation has occurred based on the determined flow noise index exceeding a predetermined flow noise threshold.

The processor may be configured to adjust (e.g., increase or decrease) the speed of the electrical machinery in response to the determined flow noise index exceeding a predetermined flow noise threshold. The adjustment in speed may be predetermined. The speed may be reduced by an absolute speed increment (e.g., reduce by 2 Hz). The speed may be adjusted by a relative speed increment (e.g., reduce by 2%). The speed may be adjusted to a speed (e.g., reduce speed to 50 Hz).

Cavitation may include gas locking and/or vapor interference.

Gas locking is a form of cavitation, caused by the presence of free gas (i.e., not dissolved, and forming a separate gaseous phase from the liquid). The compressible gas may interfere with the proper operation of the electrical rotating liquid-moving machinery (e.g., valves and other pump components), and may prevent the intake of fluid. In situations where free gas is present in fluid before it interacts with the electrical rotating liquid-moving machinery, the processor may be configured to increase the speed of the electrical machinery in response to the determined flow noise index being above the determined noise threshold. Whether the processor increases or decreases the speed of the electrical machinery in response to detecting cavitation may be predetermined (e.g., by a user based on information on the use case of the electrical rotating liquid-moving machinery). For example, a user may know that a pump is being placed in a reservoir where gas is present. In some embodiments, the processor may receive information indicating that gas is present in the fluid being pumped, and set the response to increase the speed in response to the determined flow noise index being above the determined noise threshold. The system may be configured to determine that gas is present in the fluid being pumped by determining the presence of gas before and/or after the fluid interacts with electrical rotating liquid-moving machinery. This may involve determining the physical properties of the fluid (e.g., density measurements) or the chemical composition of the fluid (e.g., detecting gaseous compounds such as methane, or carbon dioxide).

Vapor interference is another form of cavitation in which the interaction between the liquid and the electrical rotating liquid-moving machinery causes the liquid to vaporise into a gaseous state (e.g., by lowering the pressure in at least a portion of the liquid to below the vapor pressure). In situations where the motion of the electrical rotating liquid-moving machinery is causing vapor interference, the processor may be configured to decrease the speed of the electrical machinery in response to the determined flow noise index being above the determined noise threshold. Whether the processor increases or decreases the speed of the electrical machinery in response to detecting cavitation may be predetermined (e.g., based on information on the use case of the electrical rotating liquid-moving machinery). For example, the user may have knowledge of gas-water ratios in the production reservoir in which the pump is being placed. In some embodiments, the processor may receive information indicating that no significant amount of gas is present in the fluid being pumped, and set the response to decrease the speed in response to the determined flow noise index being above the determined noise threshold. The system may be configured to determine that gas is present in the fluid being pumped by determining the presence of gas before and/or after the fluid interacts with electrical rotating liquid-moving machinery. This may involve determining the physical properties of the fluid (e.g., density measurements) or the chemical composition of the fluid (e.g., detecting gaseous compounds such as methane, or carbon dioxide).

The measured electrical signals may be measured as a function of time over a period of time (e.g., over a time period of 10 s-1 minute).

In some situations, the cause of the cavitation may not be known (e.g., whether it is gas locking or vapour interference). For example, some use cases may not have the required sensors to determine whether gas is present in the fluid being pumped. In these cases, the system may be configured to make adjustments to the speed in one direction (e.g., increase or decrease), and monitor whether the situation is improving (e.g., by monitoring whether the flow noise index is increasing or decreasing). If the situation is improving, the processor may persist in the adjustments to the speed (e.g., maintain the adjustment or make a further adjustment in the same direction), but if the situation is deteriorating (e.g., the flow noise index has increased since the initial speed adjustment was made), the processor may move the speed in the opposite direction to the initial adjustment (e.g., to increase the speed instead of decreasing the speed). A PID controller may be used to monitor and implement this process. For example, if the speed is decreased and the noise increases, the PID controller may calculate that the change in speed should have the opposite sign and switch to increasing the speed.

Some embodiments may be configured to set the next change in speed to have the same direction (and possibly also magnitude) based on what resolved the issue under previous cavitation conditions. For example, if increasing the speed reduced the flow noise index in a last cavitation event (or events), the processor may be configured to increase the speed when the flow noise index next exceeds the threshold. In this way, the system can learn how best to respond to cavitation events.

The processor may be configured to adjust (e.g., increase or decrease) the speed of the electrical machinery in response to the determined flow noise index being below the predetermined noise threshold. The processor may be configured to adjust the speed of the electrical machinery in response to the determined flow noise index exceeding a predetermined flow noise threshold a predetermined number of times.

When determining the flow noise index, the processor may be configured to exclude sub-ranges of the frequency spectrum within the frequency band. Excluding sub-ranges means that the values of the frequency spectrum within these excluded sub-ranges will not affect the calculated flow noise index. That is, only the remaining portions of the frequency band will determine the calculated flow noise index.

The frequency band may span all of, or a portion of, the generated frequency spectrum.

The excluded sub-ranges may include multiples of a line frequency of the electrical machinery. Excluding multiples of the line frequency may remove the influence of the electrical signal from the flow noise index calculation.

The excluded sub-ranges may include multiples of an actual frequency of the electrical machinery. Excluding multiples of the actual frequency may remove the influence of the mechanical effects from the flow noise index calculation.

The excluded sub-ranges may correspond to peaks within the frequency band. As cavitation generally appears as noise within the frequency band, any peak within the frequency band may unduly elevate the calculated flow noise index.

The system may be configured to determine the flow noise index based only on regions of the frequency spectrum within the frequency band which is identified as noise.

The electrical signals may be parameters (e.g., current and/or voltage) of the electrical power supply used to power the electrical rotating liquid-moving machinery.

The electrical rotating liquid-moving machinery may comprise an electrical motor.

A frequency or speed of electrical rotating liquid-moving machinery may correspond to the rotational frequency of the shaft.

The frequency band may consist of frequencies higher than a motor frequency.

The frequency band may include (e.g., consist of) frequencies exceeding 200 Hz.

The frequency band may have an upper limit of at most 1 MHz.

The frequency band may comprise frequencies between 1-100 times the motor frequency. The frequency band may span frequencies between 1-100 times the motor frequency.

The electrical signals may comprise at least one voltage of the electrical rotating liquid-moving machinery.

The frequency spectrum may be a power frequency spectrum based on the measured voltage and current electrical signals.

The analog sensors may comprise: a current transformer; a Hall effect sensor and/or a Rogowski coil.

The frequency components of the measured electrical signals may be identified by applying a time-frequency transform.

The system may be configured to continuously monitor the electrical rotating liquid-moving machinery in real time.

The system may be configured to measure 3-phase electrical signals.

According to another aspect, there is provided a method for monitoring operation of electrical rotating liquid-moving machinery, the method comprising:
measuring electrical signals of the electrical rotating liquid-moving machinery, the measured electrical signals comprising at least one current;
generating a frequency spectrum based on the measured electrical signals;
determining a flow noise index corresponding to the noise present within a frequency band within the generated frequency spectrum; and
determining when cavitation has occurred based on the determined flow noise index exceeding a predetermined flow noise threshold.

The upper limit of the frequency band may be less than 200 times the line frequency.

Electrical rotating liquid-moving machinery may comprise one or more of: a pump, an agitator, an impeller, a control valve and a propeller.

The electrical rotating liquid-moving machinery may comprise an electrically driven component which rotates (e.g., a motor). The electrical rotating liquid-moving machinery may comprise a liquid-moving component which rotates (e.g., a propeller, an impeller, a rotating agitator, a gear and/or a rotating vane).

A pump may be one or more of: a centrifugal pump, a positive displacement pump, a submergible pump, a vane pump, a gear pump, a screw pump, a jet pump, a hydraulic pump, a piston pump, and a diaphragm pump.

The system may comprise analog sensors configured to measure electrical signals corresponding to the voltage and/or the current of the electrical rotating liquid-moving machinery.

The processor may be a remote processor configured to receive the measured electrical signals and to identify the frequency components of the measured electrical signals.

The identified frequency components may span the frequency range from 0 Hz (or 1 Hz) to 1 MHz. The identified frequency components may span the frequency range from 0 Hz (or 1 Hz) to 10 kHz.

The electrical signals may be measured by a plurality of sensors, each sensor being sensitive to different frequency ranges of the same parameter (e.g., voltage or current).

The remote processor may be connected to the sensor by a wired or a wireless connection.

The analog sensors may comprise one or more of: a Hall effect sensor; a Rogowski coil; and a current transformer. For systems comprising multiple analog sensors for the same parameter (e.g., current or voltage), different sensors may be used to determine that parameter in different frequency ranges, allowing the parameter to be determined across a much wider overall frequency range. For example, a Hall effect sensor may be used for relatively low frequencies and a current transformer may be used for relatively high frequencies.

The system may comprise an electrical drive. The electrical drive may be a variable frequency drive (VFD). A VFD adjusts the speed of an AC motor by varying the frequency of the power supplied to the motor. The electrical drive may be a variable speed drive (VSD). A variable speed drive may adjust the speed of the motor by adjusting the voltage and current levels.

The system may be configured for open-loop or closed-loop speed control.

The system may be configured to receive speed signals corresponding to the set speed and the actual speed of the electrical drive. It will be appreciated that, in the context of rotating machinery, a speed corresponds to a frequency (e.g., a speed of a motor may be given in Hz).

The frequency components of the measured electrical signals may be identified by applying a time-frequency transform (e.g. a Fourier Transform). Types of Fourier Transform include Fast Fourier Transform (FFT), Short-Time Fourier Transform (STFT), Discrete Fourier Transform (DFT) and Welch power spectral density. A Short-Time Fourier Transform may be useful if the state of the electrical rotating liquid-moving machinery is changing (e.g. the motor is changing speed).

The sensors may be located within a high-voltage panel and the remote processor is located outside the high-voltage panel.

The processor may be battery powered.

The processor may be configured to identify harmful or fault frequency components within the current and voltage electrical signals frequency spectra.

The measured electrical signals may be transmitted to the remote processor via one or more of: ethernet and fibre-optic cable.

The system may be configured to continuously monitor the electrical rotating liquid-moving machinery in real time.

The system may be configured to compare the frequency spectra of the current electrical signals to the frequency spectra of the voltage electrical signals.

The system may be configured to monitor the frequency spectra of the electrical signals determine changes in the frequency spectra over time.

The system may be configured to monitor how the frequency spectrum of the electrical signals varies with velocity of the electrical rotating liquid-moving machinery.

The system may be configured to measure 3-phase electrical signals.

The electrical rotating liquid-moving machinery may comprise an electrical motor.

According to a further aspect, there is provided a method for monitoring operation of electrical rotating liquid-moving machinery, comprising:
measuring analog electrical signals corresponding to the voltage and the current of the electrical rotating liquid-moving machinery;
receiving the measured electrical signals at a remote processor; and
identifying the frequency components of the measured electrical signals.

According to a further aspect, there is provided a computer program stored configured to:
receive measurements of electrical signals of the electrical rotating liquid-moving machinery, the measured electrical signals comprising at least one current;
generate a frequency spectrum based on the electrical signals measurements;
determine a flow noise index corresponding to the noise present within a frequency band within the generated frequency spectrum; and
determine when cavitation has occurred based on the determined flow noise index exceeding a predetermined flow noise threshold.

The computer program may be stored on a non-transitory medium such as a CD. The computer program may be configured to carry out the listed actions when run on a computer. The computer may comprise a memory for storing information including the computer program, and a processor configured to run the computer program.

The system may be configured to identify how quickly a cavitation condition is developing based on identifying how the flow noise index is changing.

The system may be is configured to identify a damaged component by associating an identified fault frequency with a harmonic frequency of the component. An identified fault frequency may be a frequency which does not appear when the system is running normally.

The system may be configured to identify problems based on one or more of:
determining whether the frequency spectrum has developed repeating peaks or harmonics;
determining whether the amplitude of existing peaks is changing; and/or
determining if there are new peaks (e.g. not associated with a harmonic of an existing peak).

The system may be configured to identify process related issues by identifying noise within a frequency band which is not associated with a harmonic frequency of a component of the electrical rotating liquid-moving machinery. Process related issues may include flow turbulence or other components relating to materials which are interacting with the electrical rotating liquid-moving machinery.

Pumps may have a peak in the spectrum at the “blade pass” (or “vane pass”) frequency. This is the number of blades or vanes multiplied by the shaft speed. The amplitude of the peak can increase if the gap between the blades or vanes and the stationary diffusers is not kept equal. The system may be configured to ignore frequency values corresponding to the blade pass frequency and integer multiples of the blade pass frequency when determining the flow noise index.

Rotating equipment may have a peak corresponding to the gear mesh frequency. In addition to their fundamental rotational frequencies, meshing gears produce a vibration which is the product of the number of teeth and their rotational frequency, and is an indication of machine health.

Rotating equipment may have a characteristic frequency corresponding to bearing and/or shaft eccentricity.

One or more electrical, mechanical and/or process related frequency signatures can be extracted from motor current and/or voltage. This may be considered to be condition monitoring. These features, extracted from the condition of the system, could be used for Failure Prediction.

Process related issues may be associated with the material with which the machine is interacting (e.g. a pump inducing cavities in the fluid). Mechanical faults may be associated with physical components of the machine (e.g. worn gears, broken components). Electrical faults may be associated with electrical components of the machine (e.g. windings). Power source faults may be associated with the power provided to the machine (e.g. fluctuations in the mains power itself). The system may be configured to distinguish between one or more of these types of faults.

A VFD/VSD may be configured for closed-loop and open-loop speed control.

Closed-loop speed control requires a feedback signal. A proportional, Integral and derivative controller may be used to adjust the voltage supplied to the motor to minimize the error between the motor speed and target speed.

Open control may not require feedback signals. The drive adjusting the frequency of the supplied voltage to the motor to reach the target speed.

The system may be configured to identify peaks and/or background noise within the frequency band. The system may be configured to determine the flow noise index based on the identified background noise and/or signals within the frequency band now within the identified peaks.

The processor may comprise a controller, such as a proportional-integral-derivative controller (PID controller or three-term controller). A PID controller is a control loop mechanism employing feedback that is widely used in industrial control systems and a variety of other applications requiring continuously modulated control (e.g., speed control). A PID controller continuously calculates an error value as the difference between a desired setpoint (SP) and a measured process variable (PV) and applies a correction based on proportional, integral, and derivative terms (denoted P, I, and D respectively).

The controller may comprise a proportional-integral (PI) controller. The controller may comprise a proportional-only (P) controller. It will be appreciated that, in the context of this disclosure, a PID is a type of PI controller. The controller may comprise a Fuzzy-PID controller. The controller may comprise a Fuzzy-PD and/or a Fuzzy-PI controller.

The processor may use the controller to dynamically adjust the speed of the system based on the calculated flow noise index.

In the field of machine learning and specifically the problem of statistical classification, a confusion matrix, also known as an error matrix, is a specific table layout that allows visualization of the performance of an algorithm, typically a supervised learning one. Each row of the matrix represents the instances in a predicted class while each column represents the instances in an actual class (or vice versa). The confusion matrix makes it easy to see if the system is confusing two classes (i.e. commonly mislabeling one as another).

### BRIEF DESCRIPTION OF THE DRAWINGS

Various objects, features and advantages will be apparent from the following description of particular embodiments of the present disclosure, as illustrated in the accompanying drawings. The drawings are not necessarily to scale, emphasis instead being placed upon illustrating the principles of various embodiments of the present disclosure. Similar reference numerals indicate similar components.

FIG. 1 is a schematic diagram of a first embodiment of a system for monitoring operation of electrical rotating liquid-moving machinery.

FIG. 2 is a graph of a power frequency spectrum from the embodiment of FIG. 1.

FIG. 3 is a flow chart showing how a flow noise index calculated from the power frequency spectrum may be used to control the speed of the system of FIG. 1.

FIG. 4a is a graph showing how the flow noise index and the speed of the electrical rotating liquid-moving machinery changes over time.

FIG. 4b is a graph showing how the flow rate and the speed of the electrical rotating liquid-moving machinery changes over time.

FIG. 5 is a schematic diagram of a second embodiment of a system for monitoring operation of electrical rotating liquid-moving machinery.

FIG. 6 is a graph showing how two current sensors may be used to span a greater frequency range.

### DETAILED DESCRIPTION

### Introduction

As described above, electrical rotating liquid-moving machinery can be susceptible for flow-induced vibrations such as gas lock and/or vapor interference when controlling the flow of a liquid or multi-phase fluid. Gas locking occurs due to interference of compressible gas with the proper operation of valves and pumps, preventing the intake of fluid. Vapor interference occurs when under a certain pressure and temperature a liquid portion of the multiphase fluid escapes from a liquid phase to a gaseous phase and causes no flow output. Even though these issues may not necessarily cause failure, they are a major source of unplanned downtime and interruption of operation. In oil and gas productions, these conditions are referred to as low or no-flow events. In addition, while cavitation may be more likely at higher speeds, these cavitation events can be unpredictable and occur across a range of speeds.

From a classical vibration perspective, these gas-induced conditions are defined under the general category of cavitation. If a vibration sensor were be installed on the proper location of the pump, the cavitation spectrum may be detected as random high-frequency broadband vibrations in the radial directions. That is, cavitation spectra may be characterised by a random and broadband signature whereas vibrations from mechanical or electrical defects typically appears as sharp peaks at multiples of running speed (i.e., actual frequency) or line frequency.

The recovery from no-flow events typically involves a manual try and error. The operator tries to recover the normal operation by adjusting the pump speed and/or the choke value opening. This recovery process is typically complex mainly because the pressure, temperature and fluid properties are dynamically changing. In addition, the release of the trapped gas or vapor from the equipment is slow and a function of the equipment alignment and length. The delay on the flow meters measurement is another factor. This factor is more pronounced in applications such as electric submersible pumps where the flow meter is installed several hundred meters away from the pump outlet.

The systems and methods disclosed herein include detecting and quantifying the cavitation vibrations, such as gas-locking and vapor interference, from the measured currents and voltages supplied to the electric motor. The method includes measurement of one, two or three phases current(s) and/or voltage(s) supplied to the electric motor. The method includes an index to quantify the flow-induced vibrations and identify the acceptable and unacceptable levels. Some embodiments include a method of controlling the speed of a pump using a control system. This may help allow electric process equipment such as a pump to achieve a target output while avoiding no-flow interruptions due to cavitation issues.

Various aspects of the present disclosure will now be described with reference to the figures. For the purposes of illustration, components depicted in the figures are not necessarily drawn to scale. Instead, emphasis is placed on highlighting the various contributions of the components to the functionality of various aspects of the present disclosure. A number of possible alternative features are introduced during the course of this description. It is to be understood that, according to the knowledge and judgment of persons skilled in the art, such alternative features may be substituted in various combinations to arrive at different embodiments.

### First Embodiment

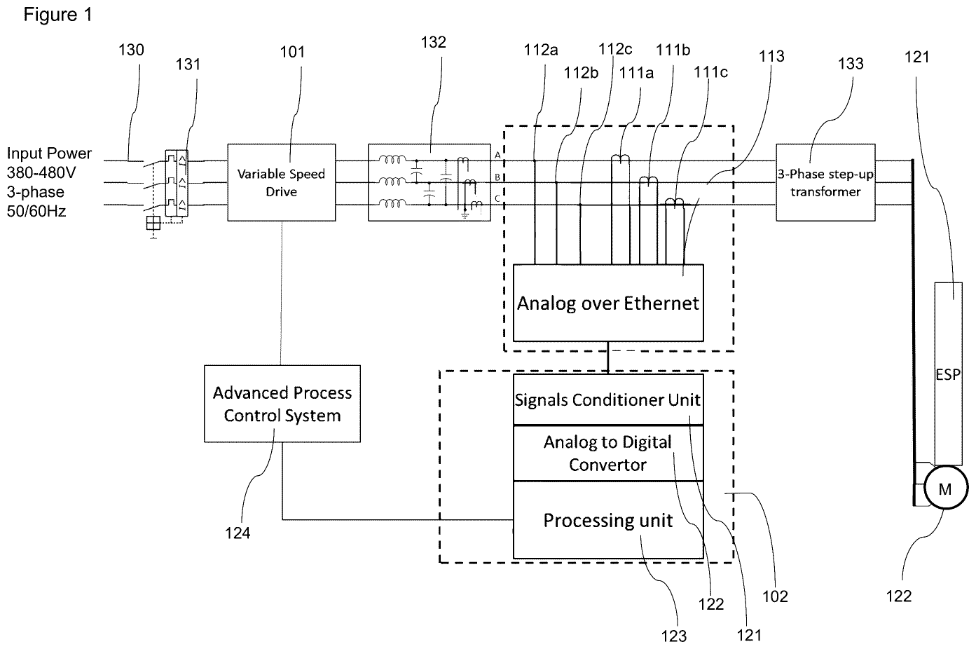

FIG. 1 illustrates an embodiment of a system for monitoring operation of electrical rotating liquid-moving machinery. In this case, the electrical rotating liquid-moving machinery comprises an electric submersible pump 121 (ESP) driven by a three-phase electrical motor 122. It will be appreciated that other electrical rotating liquid-moving machinery may not be three-phase (e.g. single phase) and/or have a different type of pump or other piece of liquid moving machinery (e.g., propeller or impeller).

The motor, in turn, is controlled in this case by a variable frequency drive 101. The variable frequency drive is powered by a three-phase power source 130. In this case, the power source is connected to the variable frequency drive 101 by an optional miniature circuit breaker designed to connect and disconnect the Variable Frequency Drive from the power source.

In this embodiment, the output of the variable frequency drive is fed through an output filter assembly 132 to remove unwanted frequency components from the output of the variable frequency drive. The output filter assembly comprises inductors in each of the lines, and capacitors across each pair of lines.

The filtered three-phase signal in this case is passed to a 3-phase step-up transformer 133 before powering the three-phase motor 122.

In this embodiment, the system compromises three current sensors 111a-c for measuring the current of each line and three voltage sensors 1121-c for measuring the voltage of each line. In this embodiment, the sensors 111a-c, 112a-c are positioned between the output filter assembly 132 and the three-phase step up transformer 133. It will be appreciated that, in other embodiments, the sensors may be placed at other positions between the variable frequency drive and the motor (e.g., after the three-phase step up transformer).

In this case, the sensor data is transmitted in analog over an ethernet electronic board 113 to transmit the measurements safely to a processor 102. In this way, the processor 102 can be remote from the possibly high voltages and currents generated by the variable frequency drive. This may help ensure that the processor is isolated from these high currents and voltages.

The processor 102, in this case, comprises an optional signal conditioner board 121 that is configured to clean the signal over the bands of interest, an analog to digital convertor (ADC) to digitize the signal 121, and a processing unit 123 for performing calculations on the cleaned digitized data. In this case, the processing unit is configured to determine a flow noise index corresponding to the noise present within a frequency band within the generated frequency spectrum; and determine when cavitation has occurred based on the determined flow noise index exceeding a predetermined flow noise threshold.

In this embodiment, the processing unit is configured to facilitate real-time communication to send the values to and receive the values from an advanced process control system 124, which in turn communicates with and/or controls the variable frequency drive 101.

### System Control

The processor is configured to determine the Flow Noise Index (FNI) from a frequency spectrum. In this embodiment, the Flow Noise Index is determined at predefined time intervals. For instance, the Flow Noise Index Flow Noise Index may be determined at one-minute intervals (other embodiments may determine the Flow Noise Index continuously or at least once every 5 minutes).

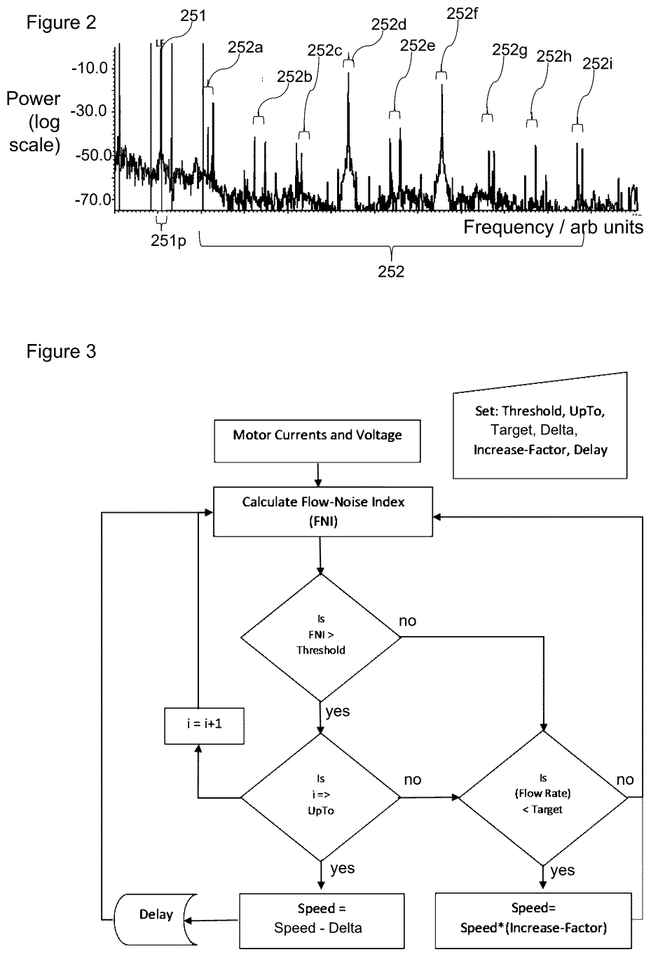

As illustrated in FIG. 2, the Flow Noise Index may be calculated from the current spectrum or power spectrum (Watt) of the motor signal as follows:

$$FNI = \frac{RMS ( frequency band - multiples of LF - multiples of RS )}{RMS ( LF )}$$

where RMS stands for root mean square; LF stands for line frequency set in the variable frequency drive which indicates the synchronous speed of the motor and RS stands for running speed which indicates the mechanical speed (or actual frequency) of the pump. It will be appreciated that other methods of determining a value or index of the noise level within the frequency band may be used.

For this calculation, the processor takes the spectral values across a wideband frequency band 252, ignoring narrower frequency ranges around multiples 252a-i (e.g., integer multiples) of the line frequency (i.e. corresponding to the target running speed or frequency) 251 and around multiples (e.g., integer multiples) of the actual running speed. These are ignored (i.e., the values are not used in the FNI calculation) in this embodiment because they may be expected to be present in a system with no cavitation, and so should not be included in a noise level calculation. In practice, other embodiments may not ignore multiples of either the line frequency and/or running speed, but the Flow Noise Index thresholds may need to be set correspondingly higher to take this into account.

With the remaining values of the spectrum within the wideband range 252, the processor is configured to calculate a noise index, which, in this embodiment involves calculating a root mean squared value (which removes changes in direction or sign which can be present in, for example, current spectra), and normalizing the rms value against the rms value of the line frequency peak 251p. This normalization takes into account the increase in noise which might be expected as the current or power delivered at the line frequency increases. The normalization also means that the flow noise index is typically expressed in terms of a percentage or ratio.

Therefore, as calculated above, the Flow Noise Index represents a value that should be relatively consistent and relatively low for electrical rotating liquid-moving machinery in normal operation across a range of speeds and power. However, when the power or speed is such that cavitation occurs, the Flow Noise Index will be significantly higher. This allows a threshold to be set between the consistent and lower value corresponding to normal operation, and the higher value corresponding to cavitation.

FIG. 3 presents a method for adjusting the speed to achieve a target production, set as Target, while avoiding, or mitigating, cavitation. In this embodiment, the motor speed is configured to gradually increase until the processor determines that cavitation is detected, or the target is met. If cavitation occurs, the motor speed is reduced by a predetermined amount and the process recommences.

In particular, if the Flow Noise Index (FNI) is greater than the acceptable threshold, Threshold, up to a number of readings, set as Up To, then the logic sets the speed to a new speed which is the current speed reduced by Delta. Delta, in this example is set at 3 Hz, so if the current speed of the pump is 56 Hz when the FNI threshold is exceeded, the processor will reduce the speed to 53 Hz (i.e., a reduction of 3 Hz).

In this case, Delta is set at an absolute value (e.g., 3 Hz). It will be appreciated that, in other embodiments or scenarios, the logic may set a relative speed adjustment which decreases the line frequency of the variable frequency drive by a predetermined amount relative to the current speed (e.g., 2-5%). In other embodiments, Delta may be between 1-10 Hz.

In this case, the Up To is an integer (e.g. between 1 and 5). E.g., if Up To is set to 3, the system will allow the FNI to exceed the threshold 3 times (i.e. in 3 measurements which may or may not be consecutive) before adjusting the speed. When the speed is adjusted, the counter variable, i, is also reset (to zero).

In this embodiment, the processor uses an adjustable delay timer positioned to delay recalculation of the FNI after the set speed of the motor has been decreased in response to cavitation. This delay is to avoid false readings (e.g. an artificially high level of noise) after a sudden drop in speed. For example, the change in the set speed may itself give a high noise reading as the motor and pump adapt to the new set speed, or as the cavitation condition resolves. The delay may be predetermined based on the type of electrical rotating liquid-moving machinery, and may be, for example, between 30 seconds and 5 minutes.

If the Index, FNI, is less than the threshold, then the logic increases the speed with an increase factor, set as Increase-Factor, until the flow rate reaches the target production.

It will be appreciated that, if the target production is below the cavitation speed of the system, then the system may never detect a FNI exceeding a threshold. In other embodiments, the system may be designed to maximise production.

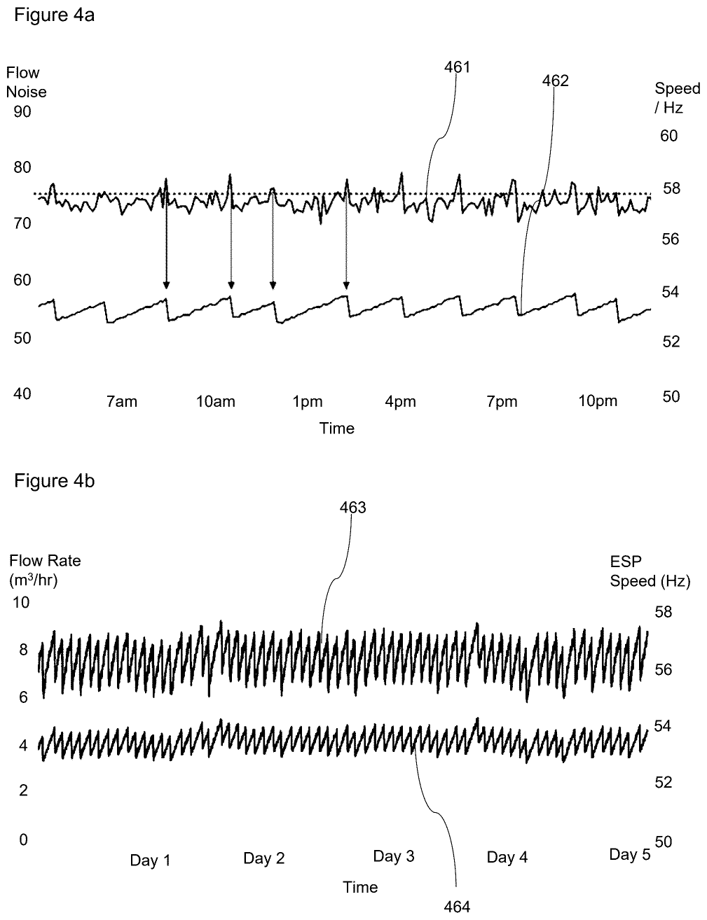

FIG. 4a shows the speed adjustment against the flow noise index. The top line 461 is the flow noise index. The bottom line 462 is the actual speed of the pump in Hertz (Hz).

In this case, the speed of the system at which cavitation becomes likely is close to the target speed. The threshold is set to 75% (Threshold=75) and the number of above threshold readings is set to 3 (Up To=3). The learning data from this pump shows the pump can not recover from zero-flow after 3 readings of flow noise (FNI) above 80%. That is, the vapor generated in the cavitations may persist even when the speed is reduced, rendering the pump inoperable. Thus, the Threshold is set 5% below the critical flow noise index to 75% in order to allow continuous operation.

FIG. 4b shows graphs of 5 days of production (output) of a pump. The top line 463 is the production of the pump in meter cubic per hour (m³/hour). The bottom line 464 is the speed of the pump in Hertz (Hz). The operator was experiencing constant zero-flow interruptions for this well at a production rate above 6.1 m³/Hr that made it almost impossible to set a production rate above 6.1 m³/hr. In the logic, an aggressive target production is set to 9 m³/hr and minimum production is set to 6 m³/Hr. On average 9% higher production per day harvested without any zero-flow events and no operator intervention.

It will be appreciated that the flow rate of a pump is usually available and can be obtained from the advanced process control system. If the flow rate readings are not available, the method is still viable. A target speed may be selected instead of a target production. As shown in FIG. 4b, the speed and flow rate are proportional.

### Second Embodiment

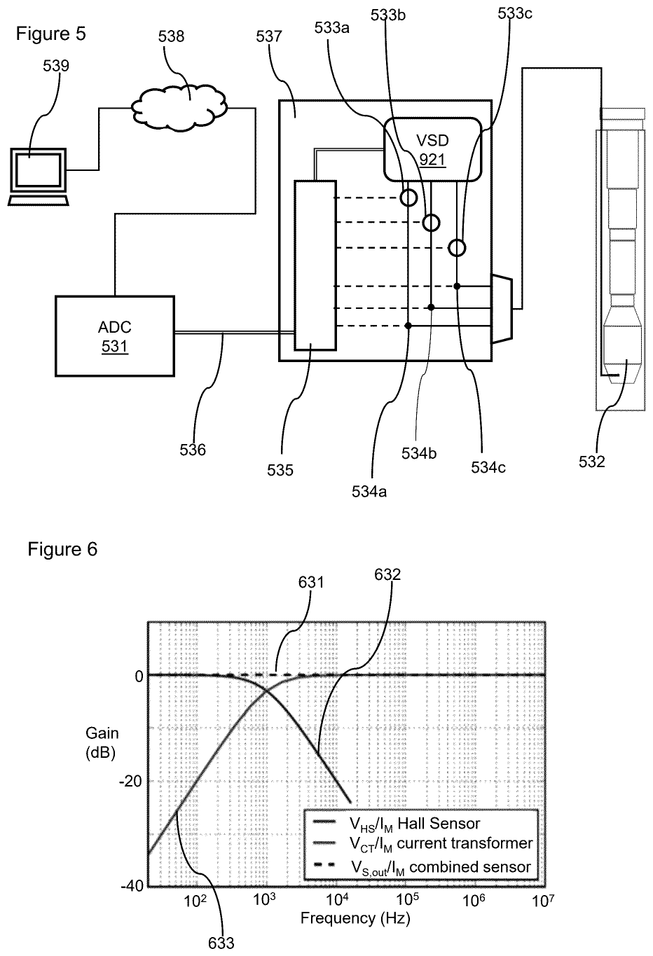

FIG. 5 shows a block diagram of the system hardware of a further embodiment. The electrical drive comprises a variable speed drive 521 (“VSD”) and is part of an artificial lift system, which comprises downhole equipment inserted into a production well (not shown). The downhole equipment includes a number of components attached to production tubing, including a pump and a pump motor 532 mechanically coupled to the pump. The pump in this embodiment is an electrically submersible pump, and alternatively can be another type of electrically driven pump known in the art such as a progressive cavity pump, a hydraulic pump, and a rod pump. A power cable extends from the VSD and into the well to couple to the pump motor.

The sensors inside the motor control panel measures the 3-phase currents and voltages, converts them to Ethernet and communicates to the ADC using Ethernet IP protocol.

This system measures 3-phase currents using wideband current sensors 533a-c installed in the motor control panel 537. The wideband is referring to the frequency response of the sensors that covers the low to high frequencies. These sensors are installed around the motor cables, as illustrated in FIG. 5. Three potential transformers 534a-c (PTs) are utilized to capture the 3-phase voltages. A small convertor 535 is designed to receive the analog signals and to send them out of the motor switchboard to an analog-to-digital convertor 531 (ADC) via a transmission line 536. The convertor may comprise an analog-to-analog conversion of the received signals (e.g. using an operational amplifier circuit).

The transmission line is an Ethernet cable in this case, but other embodiments may use fibre-optic cables.

By using the transmission cable 536, the high voltage environment can be separated from the low voltage environment. The ADC may be located at least 1.5 m (or at least 30 m and less than 3 km) from the switchbox and the high voltage components. This limits the damage and EM interference with the processor. The transmission line also allows an analog signal to be transmitted outside the switchbox, where a powerful processor can convert to a digital signal without losing resolution.

The ADC 531 is then configured to convert the signal to a digital form to be transmitted to a remote computer 539, possibly via the cloud 538.

One of the advantages of this configuration is that it allows continuous monitoring without opening the high voltage panel door of the switchboard 537. This fully complies with the National Electrical Code (NEC) for energized operating equipment. Wide band sensors allow capturing of the full range of vibrations from low to high frequencies in a continuous manner. FIG. 6 shows the frequency response of the sensors.

FIG. 6 gives the frequency response of the wideband sensors is depicted by the black dash line 631. The frequency response of the Hall effect sensors is shown by line 632 and the frequency response of the current transformer is shown by line 633. For voltage measurements, in this case, there are 3 potential difference meters that convert high voltage to a corresponding signal of between 0 to 10 Volt. This reduced signal can be transmitted outside the control panel safely, and does not interfere with other electronics.

In this embodiment, the hardware receives the analog signals over Ethernet and digitizes them. Thereby, various digital signal processing techniques in time, frequency and time-frequency may be applied for diagnostic. For instance, in time domain unbalanced current and voltage, inrush and transient current can be detected.

As with the previous embodiment, this embodiment is configured to determine when cavitation is occurring based on a flow noise index. In this case, the processor is configured to determine the noise of a high-frequency band, while ignoring peaks corresponding to multiples of the target speed and the actual speed of the rotating electrical component.

Unlike the previous embodiment, which was configured to ignore predetermined portions (frequency sub-ranges) of the frequency band based on the line frequency and the actual frequency of the system, this embodiment is configured to identify peaks and/or background noise within the frequency band.

For example, the processor may be configured to identify a particular region of the frequency band as noise by determining how correlated the values within that region, as noise is typically associated with low correlation (i.e. a random signal). Likewise, the processor may be configured to identify a peak within the frequency band by, for example, identifying a particular line shape within the signal. This embodiment is configured to ignore portions of the signal identified as a peak and/or base the calculation of the flow noise index only on the portions identified as noise.

Like the previous embodiment, a threshold for the flow noise index is set along with a target flow rate. The processor, in this case, is configured to sum the differences between the flow noise index and the threshold when the flow noise index is greater than the threshold.

When this summed value exceeds a predetermined preset sum value, the processor is configured to decrease the set speed of the variable frequency drive by a predetermined amount and reset the summed value (e.g., to zero). Then, the system is configured to periodically increase the speed of the motor in stepped increments.

It will be appreciated that the processor may or may not continue to determine the flow noise index after the new continuous set speed has been set. If the processor is configured to continue to monitor the flow noise index, it will be appreciated that if the new continuous speed is too high, the processor may continue to determine flow noise indexes exceeding the threshold, and again in response to the summed value exceeding the predetermined preset sum value, the processor is again configured to slow the pump.

It will also be appreciated that periodically the processor may be configured to again adjust (e.g., increase) the speed of the pump. This may be important where the fluid being pumped may have different characteristics at different times (e.g., pumping water, then sludge or vice versa). In this way, the system may be configured to ensure that, despite the changing characteristics, the pump is maintained at a speed just below the cavitation speed.

It will be appreciated that adjustments in speed may be based on a PID controller based on the flow noise function over time. For example, if the flow noise function increases quickly and/or exceeds the threshold by a large amount and/or for a long period of time, the system may be configured to make a greater adjustment in speed than if the flow noise function is approaching the threshold slowly and/or exceeds the threshold by a small amount and/or for a short period of time.

As described in the first embodiment, a target speed may be selected instead of a target production when the flow meter readings are not available.

Although the present invention has been described and illustrated with respect to preferred embodiments and preferred uses thereof, it is not to be so limited since modifications and changes can be made therein which are within the full, intended scope of the invention as understood by those skilled in the art.

1. A system for monitoring operation of electrical rotating liquid-moving machinery, the system comprising:
sensors configured to measure electrical signals of the electrical rotating liquid-moving machinery, the measured electrical signals comprising at least one current; and
a processor configured to:
receive the measured electrical signals and to generate a frequency spectrum based on the measured electrical signals;
determine a flow noise index corresponding to the noise present within a frequency band within the generated frequency spectrum; and
determine when cavitation has occurred based on the determined flow noise index exceeding a predetermined flow noise threshold.

2. The system according to claim 1, wherein the processor is configured to adjust the speed of the electrical machinery in response to the determined flow noise index exceeding a predetermined flow noise threshold.

3. The system according to claim 2, wherein the processor is configured to adjust the speed of the electrical machinery in response to the determined flow noise index being below the predetermined noise threshold.

4. The system according to claim 1, wherein the processor is configured to reduce the speed of the electrical machinery in response to the determined flow noise index exceeding a predetermined flow noise threshold a predetermined number of times.

5. The system according to claim 1, wherein the processor is configured to adjust a proportional, integral and derivates gain in a speed control loop in response to the determined flow noise index exceeding a predetermined flow noise threshold a predetermined number of times.

6. The system according to claim 1, wherein, when determining the flow noise index, the processor is configured to exclude sub-ranges of the frequency spectrum within the frequency band.

7. The system according to claim 6, wherein the excluded sub-ranges include multiples of a line frequency of the electrical machinery.

8. The system according to claim 6, wherein the excluded sub-ranges include multiples of an actual frequency of the electrical machinery.

9. The system according to claim 6, wherein the excluded sub-ranges correspond to peaks within the frequency band.

10. The system according to claim 1, wherein the system is configured to determine the flow noise index based only on regions of the frequency spectrum within the frequency band which is identified as noise.

11. The system according to claim 1, wherein the frequency band includes frequencies exceeding 200 Hz.

12. The system according to claim 1, wherein the frequency band comprises frequencies between 1-100 times a motor frequency.

13. The system according to claim 1, wherein the electrical signals comprise a voltage of the electrical rotating liquid-moving machinery.

14. The system according to claim 13, wherein the frequency spectrum is a power frequency spectrum based on the measured voltage and current electrical signals.

15. The system according to claim 1, wherein the analog sensors comprise: a current transformer; a Hall effect sensor and/or a Rogowski coil.

16. The system according to claim 1, wherein the frequency components of the measured electrical signals are identified by applying a time-frequency transform.

17. The system according to claim 1, wherein the system is configured to continuously monitor the electrical rotating liquid-moving machinery in real time.

18. The system according to claim 1, wherein the system is configured to measure 3-phase electrical signals.

19. A method for monitoring operation of electrical rotating liquid-moving machinery, the method comprising:
measuring electrical signals of the electrical rotating liquid-moving machinery, the measured electrical signals comprising at least one current;
generating a frequency spectrum based on the measured electrical signals;
determining a flow noise index corresponding to the noise present within a frequency band within the generated frequency spectrum; and
determining when cavitation has occurred based on the determined flow noise index exceeding a predetermined flow noise threshold.

20. A computer program stored on a non-transitory medium, the computer program being configured, when run on a computer, to:
receive measurements of electrical signals of the electrical rotating liquid-moving machinery, the measured electrical signals comprising at least one current;
generate a frequency spectrum based on the electrical signals measurements;
determine a flow noise index corresponding to the noise present within a frequency band within the generated frequency spectrum; and
determine when cavitation has occurred based on the determined flow noise index exceeding a predetermined flow noise threshold.
